(19) United States
(12) Patent Application Publication
(10) Pub. No.: US 2022/0320824 A1
(43) Pub. Date: Oct. 6, 2022

(54) Design Method, Product and Application of High-Repetition-Frequency and Multi-Wavelength Ultrashort Pulse Mode-Locked Photonic Integrated Chip

(71) Applicant: Zhejiang University, Hangzhou (CN)

(72) Inventors: Wanshu XIONG, Hangzhou (CN); Chen JI, Hangzhou (CN)

(73) Assignee: Zhejiang University, Hangzhou (CN)

(21) Appl. No.: 17/595,976

(22) PCT Filed: May 31, 2021
(86) PCT No.: PCT/CN2021/097324

§ 371 Date: Nov. 30, 2021

(30) Foreign Application Priority Data
Oct. 27, 2020 (CN) 202011166148.4

(51) Int. Cl. H01S 5/065; G02B 27/00; H01S 5/40

(52) U.S. Cl. CPC H01S 5/0657; G02B 27/0012; H01S 5/4025

(57) ABSTRACT

Disclosed are a design method, a product and an application of a high-repetition-frequency and multi-wavelength ultrashort pulse mode-locked photonic integrated chip. Components for designing the mode-locked photonic integrated chip include a semiconductor optical amplifier array providing gains for N wavelength channels; a phase delay line array which includes phase delay lines with different lengths and separately compensates for different effective optical path differences of gain light of the wavelength channels caused by a dispersion effect; a flattened arrayed waveguide grating multiplexing the gain light with the effective optical path differences compensated, and multiplexing N-channel optical pulse signals into one-channel optical pulse signal; a saturable absorber forming, with the arrayed waveguide grating, N individual and synchronized different wavelength mode-locked optical pulse channels; and a semiconductor optical amplifier used for gaining and outputting an output pulse of the saturable absorber.

### CROSS REFERENCE TO RELATED APPLICATION(S)

The present disclosure claims the priority for Chinese Patent Application No. 202011166148.4, filed to China National Intellectual Property Administration (CNIPA) on Oct. 27, 2020, and entitled “DESIGN METHOD, PRODUCT AND APPLICATION OF HIGH-REPETITION-FREQUENCY AND MULTI-WAVELENGTH ULTRASHORT PULSE MODE-LOCKED PHOTONIC INTEGRATED CHIP”, which is incorporated herein in its entirety by reference.

### TECHNICAL FIELD

The present disclosure relates to the field of compound semiconductor photonic integration, in particular to a design method, a product and an application of a high-repetition-frequency and multi-wavelength ultrashort pulse mode-locked photonic integrated chip.

### BACKGROUND ART

High-repetition-frequency and multi-wavelength semiconductor ultrashort pulse photonic integrated chips can generate multi-channel synchronized high-rate optical pulse signals with different wavelengths. In addition, they can generate high-quality optical pulse signal sequences with repetition frequencies from 100 GHz and 200 GHz to N×100 GHz through wavelength division multiplexing (WDM) technology at the end. They can also provide an ideal chip-level solution which achieves high performance, compactness, low cost and volume production for core optical pulse sources in next generation 100 GHz and later higher-speed photonic analog-to-digital converter (ADC) systems. ADCs are used to convert continuously changing analog signals in the real world into discrete digital signals that can be read and processed by computers. The ADCs figure prominently in the modern communication network system, and are widely used in radar systems, high-speed and high-resolution image and video displays, base station receivers, high-performance transmitters, controllers, and the like.

Current ADCs are mostly traditional electrical ADCs. Owing to limitation of an “electronic bottleneck”, they can only process signals with a bandwidth less than 10 GHz, and cannot reach higher speeds. With development of photoelectronic technology, the concept of photonic ADCs is put forward. It overcomes a jitter problem of the electronic ADCs by utilizing ultra-high bandwidths of photonics, breaks through the current technical bottleneck and improves the performance of the ADCs to a new level. However, based on discrete devices, current photonic ADCs have large sizes and high power consumption, causing stability of the system to be reduced accordingly, which greatly limits applications of the photonic ADCs.

At present, as internationally reported, solutions for generating multi-wavelength and short-pulse light sources mainly use spectrum cutting methods, fiber mode-locked lasers, external cavity active mode-locked lasers, etc. In all the methods for generating multi-wavelength pulses, systems generally have complex structures, and also require numerous precise optical elements, so as to be bulky and expensive. Moreover, it is difficult to achieve high-repetition-frequency pulse output through such methods, such that they are not an optimal choice for high-repetition-frequency multi-wavelength light sources applied to optical sampling and electric quantization ADCs. Although research on multi-wavelength mode-locked lasers has been proceeding domestically, it mainly focuses on the fiber mode-locked lasers.

The semiconductor mode-locked photonic integrated chips have become a research hotspot for scientists in recent years on account of compact structures, flexible wavelength tuning, high efficiency, etc. As mentioned above, the photonic ADCs are limited in application since the current optical sampling and electric quantization ADCs are based on the discrete devices, which have large sizes, high power consumption and low system stability.

At present, research on multi-wavelength semiconductor mode-locked laser chips at home and abroad has already showed some results. In 2010, Lianping Hou et al. of the University of Glasgow in the UK used quantum wells intermixing (QWI) technology to make a four-wavelength semiconductor mode-locked laser for the first time. But output frequencies of four channels are not completely consistent. California Institute of Technology previously reported an integrated chip composed of nine parallel colliding pulse mode-locked (CPM) lasers, which can only work individually. In general, each solution is defective.

### SUMMARY

In view of this, it is necessary to provide a design method and a product of a high-repetition-frequency and multi-wavelength ultrashort pulse mode-locked photonic integrated chip. The mode-locked photonic integrated chip has the features of a small size, small mass, low power consumption, high stability and optimal electromagnetic interference resistance, and is capable of outputting high-repetition-frequency and multi-wavelength ultrashort pulses.

Another objective of the present disclosure is to provide an application of a high-repetition-frequency and multi-wavelength ultrashort pulse mode-locked photonic integrated chip as an emission light source of a high-speed photonic analog-to-digital converter.

To achieve the above objective, the present disclosure provides the following solutions:

In a first aspect, according to the design method of a high-repetition-frequency and multi-wavelength ultrashort pulse mode-locked photonic integrated chip, components for designing the mode-locked photonic integrated chip include a semiconductor optical amplifier array, a phase delay line array, an arrayed waveguide grating, a saturable absorber and a semiconductor optical amplifier, adjacent components being connected through passive waveguides;

where the semiconductor optical amplifier array separately provides gains for N different wavelength channels, N being an integer greater than or equal to 2;

the phase delay line array is identical to the semiconductor optical amplifier array in dimension, and the phase delay line array includes phase delay lines which are made from passive waveguide materials and have different lengths, the phase delay lines with different lengths separately compensating for different effective optical path differences of gain light of the wavelength channels caused by a dispersion effect;

the arrayed waveguide grating is designed to be flattened and is used for multiplexing the gain light with the effective optical path differences compensated, and multiplexing N-channel optical pulse signals into one-channel optical pulse signal;

the saturable absorber is connected to an output end of the arrayed waveguide grating, and forms, with the arrayed waveguide grating, N individual and synchronized different wavelength mode-locked optical pulse channels; and

the semiconductor optical amplifier is used for gaining and outputting an output pulse of the saturable absorber.

In the design method of a mode-locked photonic integrated chip, where the saturable absorber is designed to be placed at 1/M position of a cavity length of the mode-locked photonic integrated chip, a forward current is applied to the semiconductor optical amplifier array and the semiconductor optical amplifier, and a reverse bias voltage is applied to the saturable absorber, so as to output an optical pulse with a high repetition frequency which is M times as high as a fundamental frequency.

In a second aspect, a high-repetition-frequency and multi-wavelength ultrashort pulse mode-locked photonic integrated chip is obtained through the above design method of a high-repetition-frequency and multi-wavelength ultrashort pulse mode-locked photonic integrated chip.

The mode-locked photonic integrated chip provided by the present disclosure at least has beneficial effects:

The components are connected through passive waveguides, such that all the components are closely combined together, thereby solving the problems of coupling loss between devices, incompressible sizes, high cost, large power consumption, etc. caused by discrete devices. Each wavelength is determined by the flattened arrayed waveguide grating, which eliminates complex grating fabrication and grating buried growth processes in traditional distributed feedback lasers (DFB) and distributed Bragg reflector (DBR) lasers, improves a device yield and reduces device cost. In addition, introduction of the flattened AWG makes a multi-wavelength pulse signal generated by the whole chip have narrower spectral lines and higher pulse quality.

In a third aspect, a high-speed photonic analog-to-digital converter includes the above high-repetition-frequency and multi-wavelength ultrashort pulse mode-locked photonic integrated chip as a light source.

Since the above high-repetition-frequency and multi-wavelength ultrashort pulse mode-locked photonic integrated chip has the above beneficial effects, the above high-repetition-frequency and multi-wavelength ultrashort pulse mode-locked photonic integrated chip may be perfectly applied to the high-speed photonic analog-to-digital converter, breaks through a speed bottleneck of a traditional analog-to-digital converter, and provides technical support for network construction at 100 GHz, 200 GHz and later higher speeds.

### BRIEF DESCRIPTION OF THE DRAWINGS

To describe the technical solutions in the embodiments of the present disclosure or in the prior art more clearly, the following briefly describes the accompanying drawings required in the embodiments. Apparently, the accompanying drawings in the following descriptions show merely some embodiments of the present disclosure, and a person of ordinary skill in the art can still derive other accompanying drawings from these accompanying drawings without creative efforts.

FIG. 1 is a structural schematic diagram of a high-repetition-frequency and multi-wavelength ultrashort pulse mode-locked photonic integrated chip provided by an embodiment of the present disclosure. In FIG. 1, N=10, and a 10-channel mode-locked photonic integrated chip is shown; and

FIG. 2(a) and FIG. 2(b) are a spectrogram of a Fabry-perot (FP) laser without an arrayed waveguide grating and a spectrogram of a Fabry-perot (FP) laser with an arrayed waveguide grating provided by embodiments respectively.

### DETAILED DESCRIPTION OF THE EMBODIMENTS

The following will clearly and completely describes the technical solutions in the embodiments of the present disclosure with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

To make the above objectives, features and advantages of the present disclosure clearer and more comprehensible, the following will further describe the present disclosure in detail with reference to the accompanying drawings and in conjunction with particular embodiments.

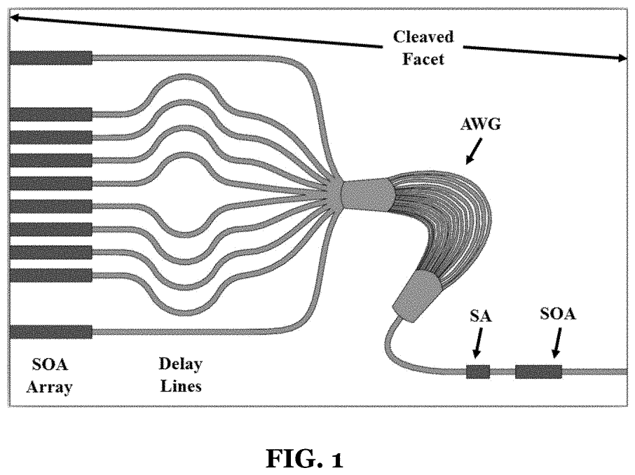

FIG. 1 is a structural schematic diagram of a high-repetition-frequency and multi-wavelength ultrashort pulse mode-locked photonic integrated chip provided by an embodiment of the present disclosure. As shown in FIG. 1, the high-repetition-frequency and multi-wavelength ultrashort pulse mode-locked photonic integrated chip sequentially includes a semiconductor optical amplifier array (SOA Array) composed of N (N being set at any integer greater than or equal to 2 per requirements) semiconductor optical amplifiers (SOA), a phase delay line array (delay lines) composed of N (the same to the number of SOAs in the SOA array) passive phase delay lines with different lengths and bending degrees, an arrayed waveguide grating (AWG), a shared saturable absorber (SA) and a semiconductor optical amplifier (SOA Amp), adjacent components being connected through passive waveguides. The N SOAs in the semiconductor optical amplifier array separately provide gains for N different wavelength channels, the passive phase delay lines with different lengths and bending degrees separately compensate for effective optical path differences of the wavelength channels caused by a dispersion effect, the flattened AWG performs wavelength selection on wide-spectrum gain light with the effective optical path differences compensated, and forms, with the shared SA connected to an output end of the AWG, N independent and synchronized wavelength mode-locked channels, and finally, the output pulse light is gained and output through the SOA Amp. During actual fabrication, the SOA array, the delay lines, the flattened AWG, the SA and the SOA Amp are fabricated on the same substrate and connected through the passive waveguides. These five components and cleaved facets at two ends of the passive waveguides connecting the five components together form the high-repetition-frequency and multi-wavelength ultrashort pulse mode-locked photonic integrated chip jointly.

During fabrication of the high-repetition-frequency and multi-wavelength ultrashort pulse mode-locked photonic integrated chip, what is required is to adjust the SOA Array and semiconductor gain materials in the SOA Array, and guarantee that the adjusted semiconductor gain materials may generate sufficient gains, so as to obtain pulse light of any wave band meeting laser output conditions. A frequency of an output pulse of the high-repetition-frequency and multi-wavelength ultrashort pulse mode-locked photonic integrated chip is also tunable in an extremely wide tunable range, for example, from one GHz to several hundred GHz. A repetition frequency of the monolithic integrated semiconductor mode-locked laser may be improved by increasing the harmonic order number, and the harmonic order may be increased by designing and adjusting a structure of the mode-locked photonic integrated chip. In the structure of the mode-locked photonic integrated chip, the SA structure is designed to be located at 1/M position of a cavity length of the mode-locked photonic integrated chip, where M may be set at any integer per requirements. A forward current is applied to an SOA Array gain region and an SOA Amp gain region on both sides of an SA region, and a reverse bias voltage is applied to the SA region, such that under certain conditions, a pulse shaping effect may be improved to output an optical pulse with a high repetition frequency which is M times as high as a fundamental frequency.

The above mode-locked photonic integrated chip achieves the mode-locked condition by introducing the semiconductor saturable absorber. During operation, the forward current is applied in the gain region to form a gain, the reverse bias voltage is applied in an absorption region to provide a mode-locked starting regime, thus obtaining output of relatively narrow continuous pulses.

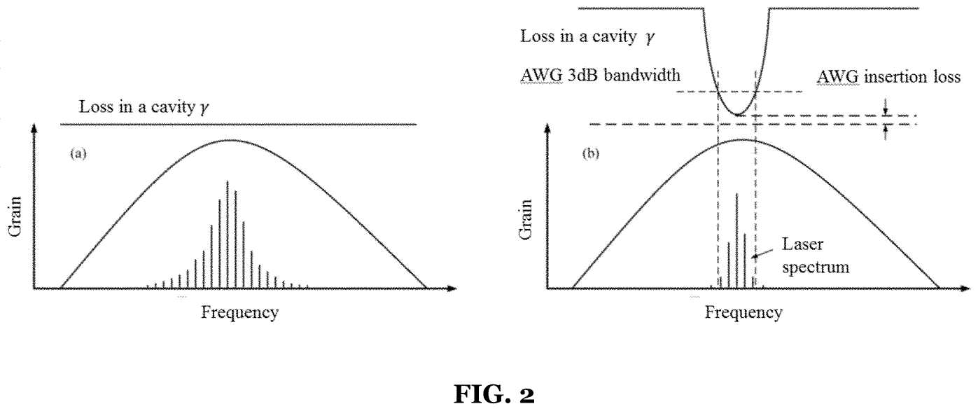

When the AWG structure is introduced into the above mode-locked photonic integrated chip, insertion loss of the AWG may directly affect a width of the optical pulse, which makes a width of the pulse through an AWG channel much wider than that of a pulse after mode-locking. FIG. 2(a) and FIG. 2(b) are a spectrogram of a laser without an arrayed waveguide grating and a spectrogram of a laser with an arrayed waveguide grating provided by embodiments respectively. It may be concluded through analysis of FIG. 2(a) and FIG. 2(b) that the insertion loss of AGW will be introduced when AWG is inserted.

In order to solve the problem that the insertion loss of the AWG affects the width of the optical pulse, in an embodiment, the flattened AWG is introduced into the mode-locked photonic integrated chip to obtain a flattened transmission bandwidth. A multimode interferometer is designed on a waveguide incident plane of the arrayed waveguide grating to improve a transmission bandwidth of the arrayed waveguide grating.

In a process of designing the mode-locked photonic integrated chip, a frequency-resolved optical grating (FROG) may be used to test a chirping feature of the output pulse signal. An FROG pulse analyzer may test an intensity and a phase of the pulse in a time domain and a frequency domain, so as to obtain all information of the pulse signal. The FROG may test the phase and chirping of a mode-locked pulse while more accurately measuring the width of the pulse.

After analysis of the chirping feature of the mode-locked pulse with the FROG, influence of a direct current (DC) source (the forward current applied to the SOA Array region and the SOA Amp gain region and the reverse bias voltage applied to the SA region) and an external radio frequency (RF) source (power and a frequency of the RF) on reducing the width of the pulse may be analyzed and researched. Therefore, the chirping of the output pulse is effectively reduced by controlling a time-bandwidth product of the mode-locked photonic integrated chip to approach a transform limitation (a fixed constant) of a pulse mode.

When the mode-locked photonic integrated chip is designed, it is also found that clock jitter of the optical pulse produced during operation of the mode-locked photonic integrated chip will directly affect performance of an optical sampling ADC. In a practical application system of the photonic ADC, the optical pulse signal output by the mode-locked photonic integrated chip needs relatively low clock jitter to meet the requirements of a 100 G ADC.

In order to greatly reduce the clock jitter of the output optical pulse signal, a hybrid mode locking manner is used for the mode-locked photonic integrated chip. Specifically, an external RF source and a bias tee are added to the saturable absorber, and a reverse bias voltage applied to the saturable absorber and a RF clock signal are combined together by the bias tee, to be applied to the saturable absorber by a ground-signal (GS) probe, so as to realize hybrid mode locking.

During research, it is found that the width of the output pulse signal of the mode-locked photonic integrated chip is sensitive to a tuning frequency and output power of the external RF clock source. Therefore, the clock jitter of the optical pulse of the mode-locked photonic integrated chip is reduced by optimizing the output frequency and the output power of the RF clock signal in the embodiment. Through research, it is found that when the output power of the RF clock signal is greater than 20 dBm, the clock jitter of the optical pulse is reduced to 1 ps or below.

The above mode-locked photonic integrated chip has the features of a small size, small mass, low power consumption, high stability and optimal electromagnetic interference resistance, and therefore may be volume-produced conveniently in the future for network construction and deployment. Moreover, a high-repetition frequency multi-wavelength short pulse source will be extensively and significantly applied in a core network based on current wavelength division multiplexing (WDM) technology, even in the next generation hybrid optical time division multiplexing-wavelength division multiplexing (OTDM-WDM) core network and a passive optical access network (OTDM-WDM PON).

The embodiment also provides a high-speed photonic analog-to-digital converter. The above high-repetition-frequency and multi-wavelength ultrashort pulse mode-locked photonic integrated chip serves as a light source of the high-speed photonic analog-to-digital converter.

Since the above high-repetition-frequency and multi-wavelength ultrashort pulse mode-locked photonic integrated chip has the above beneficial effects, it may be perfectly applied to the high-speed photonic analog-to-digital converter, and the mode-locked photonic integrated chip is utilized to generate an ultrastable optical pulse train for sampling, and may be applied to a photonic ADC with a high sampling rate.

Each embodiment in the specification is described in a progressive manner, each embodiment focuses on differences with another embodiment, and the embodiments may refer to one another for the same and similar portions. For the system disclosed in the embodiments, since the system corresponds to the method disclosed in the embodiments, and description is relatively simple, reference can be made to description of the method for relevant contents.

In the specification, particular embodiments are used for illustrating the principles and embodiments of the present disclosure. The above description of the embodiments is merely used to facilitate understanding of the method of the present disclosure and the core ideas thereof. In addition, a person of ordinary skill in the art can make modifications in terms of particular embodiments and an application scope in accordance with the ideas of the present disclosure. In conclusion, the content of the specification shall not be construed as a limitation to the present disclosure.

1. A design method of a high-repetition-frequency and multi-wavelength ultrashort pulse mode-locked photonic integrated chip, wherein components for designing the mode-locked photonic integrated chip comprise a semiconductor optical amplifier array, a phase delay line array, an arrayed waveguide grating, a saturable absorber and a semiconductor optical amplifier, adjacent components being connected through passive waveguides;
wherein the semiconductor optical amplifier array separately provides gains for N different wavelength channels, N being an integer greater than or equal to 2;
the phase delay line array is identical to the semiconductor optical amplifier array in dimension, and the phase delay line array comprises phase delay lines which are made from passive waveguide materials and have different lengths, the phase delay lines with different lengths separately compensating for different effective optical path differences of gain light of the wavelength channels caused by a dispersion effect;
the arrayed waveguide grating is designed to be flattened and is used for multiplexing the gain light with the effective optical path differences compensated, and multiplexing N-channel optical pulse signals into one-channel optical pulse signal;
the saturable absorber is connected to an output end of the arrayed waveguide grating, and forms, with the arrayed waveguide grating, N individual and synchronized different wavelength mode-locked optical pulse channels; and
the semiconductor optical amplifier is used for gaining and outputting an output pulse of the saturable absorber.

2. The design method of a high-repetition-frequency and multi-wavelength ultrashort pulse mode-locked photonic integrated chip according to claim 1, wherein the saturable absorber is designed to be placed at 1/M position of a cavity length of the mode-locked photonic integrated chip, a forward current is applied to the semiconductor optical amplifier array and the semiconductor optical amplifier, and a reverse bias voltage is applied to the saturable absorber, so as to output an optical pulse with a high repetition frequency which is M times as high as a fundamental frequency.

3. The design method of a high-repetition-frequency and multi-wavelength ultrashort pulse mode-locked photonic integrated chip according to claim 1, wherein a multimode interferometer is designed on a waveguide incident plane of the arrayed waveguide grating to improve a transmission bandwidth of the arrayed waveguide grating.

4. The design method of a high-repetition-frequency and multi-wavelength ultrashort pulse mode-locked photonic integrated chip according to claim 1, wherein chirping of the output pulse is reduced by controlling a time-bandwidth product of the mode-locked photonic integrated chip to approach a transform limitation of a pulse mode.

5. The design method of a high-repetition-frequency and multi-wavelength ultrashort pulse mode-locked photonic integrated chip according to claim 1, wherein an external radio frequency (RF) source and a bias tee are added to the saturable absorber, and a reverse bias voltage applied to the saturable absorber and a RF clock signal are combined together by the bias tee, to be applied to the saturable absorber by a ground-signal probe, so as to realize hybrid mode locking.

6. The design method of a high-repetition-frequency and multi-wavelength ultrashort pulse mode-locked photonic integrated chip according to claim 5, wherein clock jitter of an optical pulse of the mode-locked photonic integrated chip is reduced by optimizing output power and an output frequency of the RF clock signal.

7. The design method of a high-repetition-frequency and multi-wavelength ultrashort pulse mode-locked photonic integrated chip according to claim 6, wherein the output power of the RF clock signal is greater than 20 dBm.

8. A high-repetition-frequency and multi-wavelength ultrashort pulse mode-locked photonic integrated chip, wherein it is obtained through the design method of a high-repetition-frequency and multi-wavelength ultrashort pulse mode-locked photonic integrated chip according to claim 1.

9. The high-repetition-frequency and multi-wavelength ultrashort pulse mode-locked photonic integrated chip according to claim 8, wherein the saturable absorber is designed to be placed at 1/M position of a cavity length of the mode-locked photonic integrated chip, a forward current is applied to the semiconductor optical amplifier array and the semiconductor optical amplifier, and a reverse bias voltage is applied to the saturable absorber, so as to output an optical pulse with a high repetition frequency which is M times as high as a fundamental frequency.

10. The high-repetition-frequency and multi-wavelength ultrashort pulse mode-locked photonic integrated chip according to claim 8, wherein a multimode interferometer is designed on a waveguide incident plane of the arrayed waveguide grating to improve a transmission bandwidth of the arrayed waveguide grating.

11. The high-repetition-frequency and multi-wavelength ultrashort pulse mode-locked photonic integrated chip according to claim 8, wherein chirping of the output pulse is reduced by controlling a time-bandwidth product of the mode-locked photonic integrated chip to approach a transform limitation of a pulse mode.

12. The high-repetition-frequency and multi-wavelength ultrashort pulse mode-locked photonic integrated chip according to claim 8, wherein an external radio frequency (RF) source and a bias tee are added to the saturable absorber, and a reverse bias voltage applied to the saturable absorber and a RF clock signal are combined together by the bias tee, to be applied to the saturable absorber by a ground-signal probe, so as to realize hybrid mode locking.

13. The high-repetition-frequency and multi-wavelength ultrashort pulse mode-locked photonic integrated chip according to claim 12, wherein clock jitter of an optical pulse of the mode-locked photonic integrated chip is reduced by optimizing output power and an output frequency of the RF clock signal.

14. A high-speed photonic analog-to-digital converter, comprising the high-repetition-frequency and multi-wavelength ultrashort pulse mode-locked photonic integrated chip according to claim 6 as a light source.
